(19) United States
(12) Patent Application Publication
(10) Pub. No.: US 2026/0059647 A1
(43) Pub. Date: Feb. 26, 2026

(54) PRINTED CIRCUIT BOARD ASSEMBLY

(71) Applicant: Rolls-Royce Deutschland Ltd & Co KG, Blankenfelde-Mahlow (DE)

(72) Inventors: Uwe WALTRICH, Forchheim (DE); Stanley BUCHERT, Herzogenaurach (DE); Marco BOHLLÄNDER, Hirschaid (DE)

(21) Appl. No.: 19/102,541

(22) PCT Filed: Aug. 7, 2023
(86) PCT No.: PCT/EP2023/071817

§ 371 Date: Feb. 10, 2025

(30) Foreign Application Priority Data
Aug. 11, 2022 (DE) 10 2022 120 294.1

(51) Int. Cl. H05K 1/02

(52) U.S. Cl. CPC H05K 1/0204; H05K 2201/10409

(57) ABSTRACT

A printed circuit board assembly includes a printed circuit board with an upper face, a lower face, multiple metal layers, and multiple electrically insulating layers. The printed circuit board assembly additionally includes a metal heat sink on which the lower face of the printed circuit board lies at least in some regions, wherein the metal heat sink has a heat sink potential. The bottom metal layer of the printed circuit board is set to the heat sink potential while the other metal layers of the printed circuit board have an electric potential which deviates therefrom.

The present patent document is a § 371 nationalization of PCT Application Serial No. PCT/EP2023/071817, filed Aug. 7, 2023, designating the United States, and this patent document also claims the benefit of German Patent Application No. 10 2022 120 294.1, filed Aug. 11, 2022, which are incorporated by reference in their entireties.

### TECHNICAL FIELD

The disclosure relates to a printed circuit board assembly.

### BACKGROUND

Power electronics assemblies, which are based on printed circuit boards and in which power semiconductors embedded in electrical modules are soldered to the underside of a multilayer printed circuit board or carrier board and make electrical contact therewith, are known. The electrical modules, which are each provided with a power semiconductor, are also referred to as prepackage modules. For cooling the prepackage modules, it is known that the prepackage modules protrude into cavities of a heat sink and are pressed against the heat sink via a thermal interface material TIM. The carrier board rests on the heat sink to the side of these cavities, with the result that the carrier board itself is also cooled by the heat sink.

A multilayer printed circuit board or carrier board includes metal layers and electrically insulating layers. The metal layers may be copper layers. The electrically insulating layers may be layers made of FR4 material that include epoxy resin and glass fiber fabric. When prepackage modules with power semiconductors are arranged on a carrier board, as considered in the present case, the internal copper layers of the carrier board are at a high-voltage potential, for example, approximately 1000 V. The electrically insulating layers of the carrier board and a thermal interface material, which may be arranged between the carrier board and the heat sink, provide electrical insulation between the metal layers of the carrier board and the electrical potential of the heat sink, which is 0 V, for example.

However, there is the problem that it is not possible to avoid the thermal interface material containing air pockets. Thus, air pockets are either contained in the thermal interface material itself or they are produced at the interface between the thermal interface material and the printed circuit board. Since air has a significantly lower permittivity than the electrically insulating layers of the carrier board (e.g., FR4), a significantly stronger electric field is created in the air pockets than in the insulating layers of the carrier board. At the same time, air has a low dielectric strength, and so air pockets pose the significant risk of partial discharges. Partial discharges result in degradation of the printed circuit board material and thus reduce the insulation properties and the service life of the printed circuit board. To solve this problem, it is known to make the electrically insulating layers of the carrier board thicker or to arrange the carrier board at a distance from the heat sink. However, this impairs the thermal connection of the carrier board to the heat sink and increases the space requirements and material costs.

### SUMMARY AND DESCRIPTION

The disclosure is based on the object of providing a printed circuit board assembly having an electrical printed circuit board and a heat sink, which provides effective electrical insulation between the metal layers of the printed circuit board and the heat sink, in which the risk of partial electrical discharges is reduced.

This object is achieved by a printed circuit board assembly as described herein. The scope of the present disclosure is defined solely by the appended claims and is not affected to any degree by the statements within this summary. The present embodiments may obviate one or more of the drawbacks or limitations in the related art.

Accordingly, a printed circuit board assembly includes a printed circuit board having a top side and an underside, a plurality of metal layers, and a plurality of electrically insulating layers. The printed circuit board assembly further has a metal heat sink on which the underside of the printed circuit board rests at least in certain areas. The metal heat sink has a defined electrical potential which is referred to as the heat sink potential in the context of the present disclosure.

Provision is made for the lowest metal layer of the printed circuit board to be put at the heat sink potential, while the other metal layers of the printed circuit board have a different electrical potential.

The solution is based on the idea of shifting the potential difference between the heat sink potential and the high-voltage potential of the metal layers into the printed circuit board, namely between the lowest metal layer of the printed circuit board and the metal layers arranged above it. This is achieved by putting the lowest metal layer of the printed circuit board at the same potential as the heat sink. The lowest metal layer of the printed circuit board serves as a shield, wherein the electrical field associated with the potential difference remains within the printed circuit board. Accordingly, the electrically insulating layer (for example, FR4 material) between the lowest metal layer and the metal layer adjoining it serves as the only insulating layer for insulating the carrier board from the heat sink. However, in contrast to air, the electrically insulating layer of the printed circuit board has a significantly higher dielectric strength, which is why the risk of partial discharges is minimized.

In contrast, there is no potential difference or electrical voltage between the lowest metal layer of the printed circuit board and the heat sink, and so there is no risk of partial discharges into the heat sink. The solution thus reduces the risk of partial discharges and thus improves the insulation properties and the service life of the printed circuit board or the carrier board.

Another advantage associated with the disclosure is that, due to the fact that the risk of partial discharges between the printed circuit board and the heat sink is avoided, lower requirements need to be imposed on a thermal interface material arranged between the printed circuit board and the heat sink for thermal connection. In particular, it is harmless if there are air pockets in such a thermal interface material. The solution thus also enables an effective thermal connection of the printed circuit board to the heat sink and an improvement in the cooling of components arranged on the top side of the printed circuit board.

For the purposes of the present disclosure, the side of the printed circuit board that faces the heat sink is referred to as the underside of the printed circuit board, irrespective of the spatial orientation of the printed circuit board and the heat sink.

In certain examples, the lowest metal layer is a lower outer layer of the printed circuit board. In this configuration, the lowest layer of the printed circuit board, which represents the lower outer layer, is thus formed by a metal layer. This lower outer layer is put at the heat sink potential.

Alternatively, provision may be made for the lowest metal layer of the printed circuit board to be formed by an inner layer. In this case, the lowest metal layer is the lowest inner layer of the metal layers of the printed circuit board. In this design variant, this is put at the heat sink potential.

In certain examples, the further metal layers of the printed circuit board that are not at the heat sink potential may be at the same or different potentials. For example, they are at a high-voltage potential.

So that the lowest metal layer of the printed circuit board is at the potential of the heat sink, the lowest metal layer and the heat sink may be connected to each other by a short-circuit path that provides an electrical short circuit between the lowest metal layer and the heat sink.

One configuration provides for this at least one screw connection that is provided and set up to press the printed circuit board against the heat sink. Provision may be made for the lowest metal layer of the printed circuit board to be put at the heat sink potential via the screw connection. The screw connection provides an electrical short circuit between the heat sink and the lowest metal layer.

In one configuration, the lowest metal layer is put at the potential of the heat sink by means of one or more screw connections by virtue of the screw connection including a metal screw which extends through a mounting hole of the printed circuit board and is screwed into the metal heat sink, the mounting hole having a circumferential metallization in the printed circuit board plane in which the lowest metal layer is formed, and the circumferential metallization being in electrical contact with or formed by the lowest metal layer.

The lowest metal layer is put at the potential of the heat sink via the circumferential metallization and the metal screw. The circumferential metallization and the metal screw form a short-circuit path between the heat sink and the lowest metal layer.

For example, the potential of the heat sink is the ground potential, for example the grounded ground potential. In principle, however, the heat sink may also have a different potential, wherein it is only necessary for the potential of the further metal layers of the printed circuit board to differ from the potential of the heat sink. For example, the other metal layers of the printed circuit board, which are not subjected to the heat sink potential, are subjected to a high-voltage potential. Despite the large potential difference between the adjacent metal layers, the risk of partial discharges is minimized, since the electrically insulating layer (e.g., FR4) arranged between these metal layers has a significantly higher dielectric strength than air.

In certain examples, the lowest metal layer covers at least ⅔, at least ¾, or at least ⅘ of the printed circuit board surface. The greater the percentage surface coverage of the printed circuit board by the lower metal layer, the better the provided shielding and safety against partial discharges.

A further configuration provides at least one electrical module arranged on the underside of the printed circuit board, wherein the heat sink has a cavity into which the electrical module protrudes, and wherein the printed circuit board rests on the heat sink in a manner adjacent to the cavity. This provides a particularly effective design in which effective cooling of the electrical modules takes place, the printed circuit board resting on the heat sink to the side of the cavity via a thermal interface material is also cooled and at the same time the risk of partial discharges is minimized.

In certain examples, the electrical module includes: a ceramic circuit carrier which has an insulating ceramic layer and an upper metallization layer arranged on the top side of the ceramic layer; an electrical component which is arranged on the top side of the upper metallization layer and is electrically connected thereto; a top side of the electrical module, which is arranged on the underside of the printed circuit board; and an underside of the electrical module.

For example, the underside of the electrical module is thermally coupled to the heat sink via a thermal interface material.

The electrical component is, for example, the actual power semiconductor such as, for example, a power MOSFET or an IGBT component. The ceramic circuit carrier serves for electrical insulation of the electrical component from the heat sink and at the same time for thermal connection to the heat sink. In this case, the ceramic circuit carrier, together with the semiconductor component and a sheath, for example made of encapsulating material, forms the electrical module which may be connected to the printed circuit board or a carrier board via contacts formed on its surface. Such an electrical module is also referred to as a prepackage module.

### BRIEF DESCRIPTION OF THE DRAWINGS

The disclosure is now explained in greater detail below by a plurality of embodiments and with reference to the figures of the drawing, in which:

FIG. 1 depicts an embodiment of a printed circuit board assembly having a printed circuit board, electrical modules arranged on the underside of the printed circuit board and a heat sink, wherein the underside of the printed circuit board rests on the heat sink in certain areas and a lowest metal layer of the printed circuit board is put at the electrical potential of the heat sink.

FIG. 2 depicts an example of a section of a printed circuit board assembly according to FIG. 1, in which the printed circuit board rests on the heat sink via a thermal interface material, wherein a lowest metal inner layer of the printed circuit board is put at the electrical potential of the heat sink.

FIG. 3 depicts an example of a section of a printed circuit board assembly according to FIG. 1, in which the printed circuit board rests on the heat sink via a thermal interface material, wherein a lowest metal outer layer of the printed circuit board is put at the electrical potential of the heat sink.

FIG. 4 depicts an example of a sectional representation of the printed circuit board assembly from FIG. 1 in the area of a screw connection via which the printed circuit board is screwed to the heat sink, wherein the screw connection has a metal screw and a circumferential metallization which provide an electrical short circuit between the heat sink and the lowest metal layer of the printed circuit board.

FIG. 5 depicts the printed circuit board assembly from FIG. 4 in a view of the printed circuit board from below, wherein the printed circuit board is provided on its underside with a lowest metal layer and contact is made with the lowest metal layer by the circumferential metallization of the screw connection.

FIG. 6 depicts an embodiment of an electrical module in the form of a prepackage module.

### DETAILED DESCRIPTION

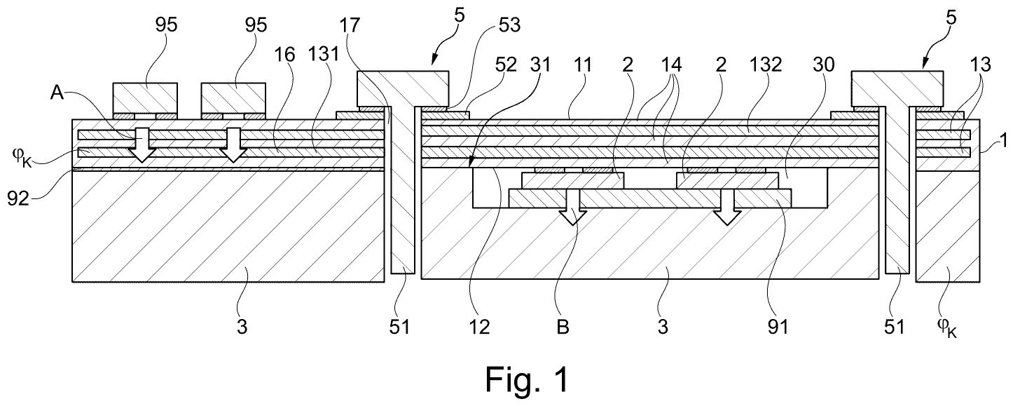

FIG. 1 shows a printed circuit board assembly including a printed circuit board 1 and a heat sink 3. The printed circuit board 1 is composed of a multiplicity of printed circuit board layers arranged above one another. The printed circuit board layers include metal layers 13 and electrically insulating layers 14 arranged between the metal layers 13. The metal layers 13 are, for example, copper layers. The electrically insulating layers are, for example, material layers made of FR4. In this case, a top printed circuit board layer forms a top side 11 of the printed circuit board 1 and a lowest printed circuit board layer forms an underside 12 of the printed circuit board 1.

Electrical modules 2 are arranged on the underside 12 of the printed circuit board 1. The connection to the printed circuit board 1 is effected, for example, by surface mounting or through-hole mounting. In addition, electrical components 95 may also be arranged on the top side 11 of the printed circuit board 1. The modules 2 are active modules that include, for example, power electronics components or assemblies and require cooling by way of the heat sink 3. For this purpose, the heat sink 3 has a recess 30 into which the modules 2 to be cooled protrude.

To improve the thermal connection, provision is made for a thermal interface material 91 to be arranged between the modules 2 to be cooled and the heat sink 3. The thermal interface material 91 is, for example, a heat-conducting mat.

The printed circuit board 1 is screwed to the heat sink 3 by means of screw connections 5. The screw connections 5 include metal screws 51 that extend through a mounting hole 17 of the printed circuit board 5 and are screwed into the metal heat sink 3. The metal screws 51 rest on the top side 11 of the printed circuit board 1 via a washer 52 and a metallization 53, for example. They provide a pressure force with which the printed circuit board 1 is pressed against the heat sink 3. In particular, they provide the pressure force with which the modules 2 to be cooled, which are arranged on the underside 2 of the printed circuit board, are pressed against the surface of the heat sink 3 in order to provide a good thermal transition.

The heat sink 3 may have numerous configurations. For example, the heat sink 3 is made of a metal such as, for example, aluminum or an aluminum alloy and has cooling surfaces (not shown separately). The heat sink 3 may be an active heat sink, which is actively cooled by a fan (not shown) or liquid cooling (not shown), or a passive heat sink.

Outside the cavity 30, the underside 12 of the printed circuit board 1 rests on the top side 31 of the metal heat sink 3. The top side 31 of the heat sink 3 is flat in the same way as the underside 12 of the printed circuit board 1 and the two surfaces run parallel to each other. Provision is made for a thermal interface material 92 to be arranged between the underside 12 of the printed circuit board 1 and the top side 31 of the metal heat sink 3 in order to improve the thermal connection of the printed circuit board 1 to the heat sink 3. The thermal interface material 92 is, for example, a heat-conducting mat or a large-area adhesive film made of TIM material. In the area in which the printed circuit board 1 rests on the heat sink 3 via the thermal interface material 92, the printed circuit board 1 and the electrical components 95 arranged on the top side 11 of the printed circuit board 1 are cooled.

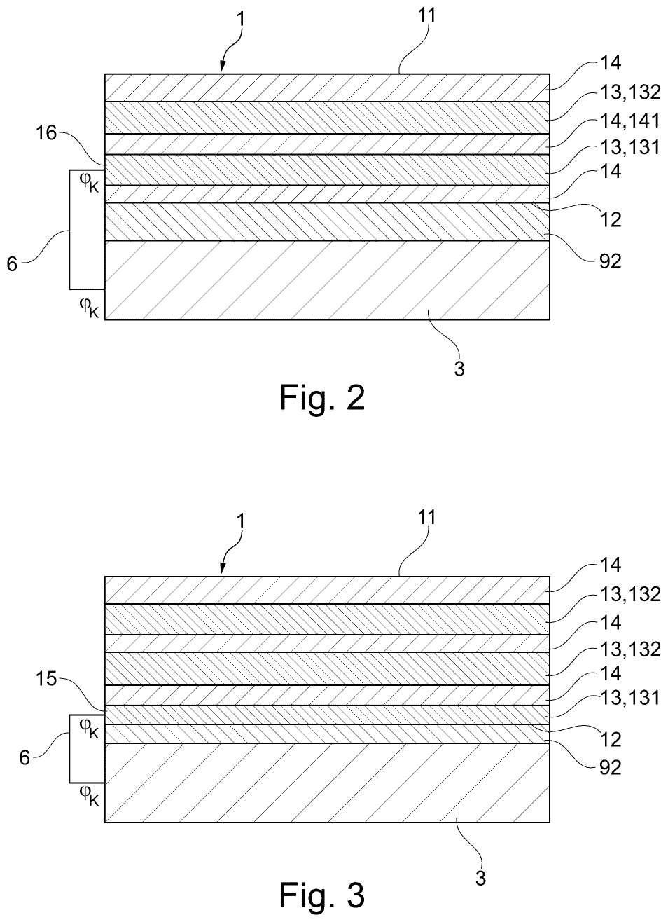

The heat sink 3 is at a defined electrical potential φ_{K}, which is equal to the ground potential and is, for example, 0 V or a low voltage. In contrast, the metal layers 13 of the printed circuit board 1 are at a high-voltage potential of, for example, approximately 1000 V. Provision is made for the lowest metal layer 131 of the printed circuit board 1 to also be put at the electrical potential φ_{K} of the heat sink 3. The manner in which this is effected and variants thereof are described in FIGS. 2-5. This causes the lowest metal layer 131 of the printed circuit board 1 to act as a shield. The electrical field generated by the large voltage difference of, for example, 1000 V remains within the printed circuit board 1, wherein the electrically insulating layer 14 between the lowest metal layer 131 and the further metal layer 132 arranged above it serves as the only insulation layer for insulating the printed circuit board 1 from the heat sink 3.

If, on the other hand, the lowest metal layer 131 of the printed circuit board was also subjected to a high-voltage potential, as is known in the prior art, the electrical field associated with the voltage difference would extend between the underside 12 of the printed circuit board 1 and the top side 31 of the heat sink 3 and thereby through the thermal interface material 92. In such a case, there would be the significant risk of air pockets in the thermal interface material 92 entailing partial discharges, since air has a lower permittivity compared to material used in printed circuit boards to form electrically insulating layers (e.g., FR4). For example, air has a permittivity of approximately one, whereas the material FR4 has a permittivity in the region of five. Since the electric field strength increases with falling permittivity values, an increased field strength occurs in air. Such a behavior is known in high-voltage technology in layered insulation systems as the field displacement effect, in which case the electric field is displaced into the insulating material with the lower permittivity. Since air also has a lower dielectric strength, the risk of partial discharges is increased. These problems are avoided by subjecting the lowest metal layer 131 to the heat sink potential.

Provision is made for the lowest metal layer 131 to cover a substantial area of the printed circuit board 1 so that said shielding is effectively achieved, for example, at least ⅔, at least ¾, or at least ⅘ of the surface of the printed circuit board 1.

FIG. 1 also shows heat-conducting paths A from the printed circuit board 1 into the heat sink 3 and heat-conducting paths B from the electrical modules 2 into the heat sink 3.

FIG. 2 shows an enlarged representation of an area of the printed circuit board 1 from FIG. 1, which rests on the heat sink 3 via a thermal interface material 92, that is to say, shows an area laterally spaced apart from the cavity 30 of the heat sink 3.

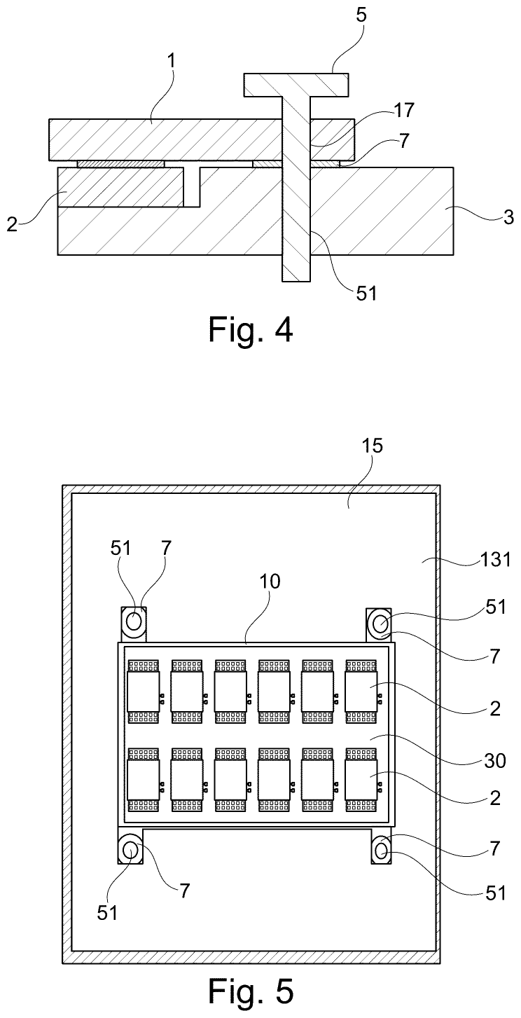

As explained, the printed circuit board 1 includes a plurality of metal layers 13 (for example, copper layers) and a plurality of electrically insulating layers 14 (for example, layers made of FR4 material). A thermal interface material 92 is arranged between the underside 12 of the printed circuit board 1 and the metal heat sink 3. The situation here is such that the metal heat sink 3 has a potential φ_{K}, which is, for example, the ground potential. A schematically shown short-circuit path 6 is provided and electrically connects the heat sink 3 to the lowest metal layer 131 of the metal layers 13. The short-circuit path 6 is only shown schematically. An example for implementing the short-circuit path 6 is explained using FIGS. 4 and 5.

The further metal layer 132 arranged above the metal layer 131 is subjected, on the other hand, to a high-voltage potential of, for example, 1000 V. The only insulation layer between the two metal layers 131, 132 is provided by the electrically insulating layer 141 located between them. This has a comparatively high permittivity, which contributes to reducing the local electric field. It also has a significantly higher dielectric strength compared to air, thus minimizing the risk of partial discharges.

In the embodiment in FIG. 2, the lowest metal layer 131 represents a lowest inner layer 16 of the printed circuit board 1 and thus does not form an outer layer.

FIG. 3 shows an embodiment that corresponds to the embodiment in FIG. 2 apart from the fact that the lowest metal layer 131 forms a lower outer layer 15 of the printed circuit board. A schematically shown short-circuit path 6 is again implemented between the heat sink 3 and the lowest metal layer 131, with the result that the lowest metal layer 131 is put at the heat sink potential φ_{K}. The further metal layers 132 arranged above the outer layer 15 or the lowest metal layer 131, on the other hand, are at a high-voltage potential, in which case they may be subjected to the same potential or alternatively to a different potential.

FIGS. 4 and 5 show an embodiment for implementing the short-circuit path 6 shown only schematically in FIGS. 2 and 3. Provision is made for the short-circuit path to be implemented via the screw connection 6. According to FIG. 4, the screw connection 5 includes a metal screw 51 which extends through a mounting hole 17 in the printed circuit board 1 and is screwed into the metal heat sink 3, with the result that the metal screw 51 is at the heat sink potential φ_{K}. Provision is also made for the mounting hole 17 to have a circumferential metallization 7 in the printed circuit board plane in which the lowest metal layer 131 is formed. The circumferential metallization 7 is formed, for example, by circumferential copper plating. The circumferential metallization 7 is also put at the heat sink potential φ_{K} via the metal screw 51.

In the embodiment in FIG. 4, the circumferential metallization 7 is formed in the plane of the lower outer layer 15, which is formed by the lowest metal layer 131, as may be seen from FIG. 5. This corresponds to the exemplary embodiment in FIG. 3. Alternatively, the lowest metal layer 131 could be an inner layer according to FIG. 2. For this case, the circumferential metallization 7 was formed in the plane of this inner layer.

The circumferential metallization 7 is in electrical contact with the lowest metal layer 131 or merges into it, as may be seen from FIG. 5. This means that the lowest metal layer 131 is also put at the heat sink potential φ_{K}.

The electrical contact surfaces on the underside of the printed circuit board 1 in the area of the cavity 30, which serve to make contact with the electrical modules 2, are each connected, (for example, via vias), to a metal layer of the printed circuit board that is at a high-voltage potential.

FIG. 5 is a hybrid representation insofar as the area 10 in which the electrical modules 2 protrude into a cavity 30 of the heat sink 3 is shown in a view from above, while, outside the area 10, FIG. 5 is a view of the lowest metal layer 131 or outer layer 15 of the printed circuit board 1 from below.

The provision of a short-circuit path according to the configuration in FIGS. 4 and 5 should be understood merely as an example. Alternatively, it is possible to provide additional conductive structures or electrical conductors that put the lowest metal layer 131 of the printed circuit board 1 at the heat sink potential φ_{K}.

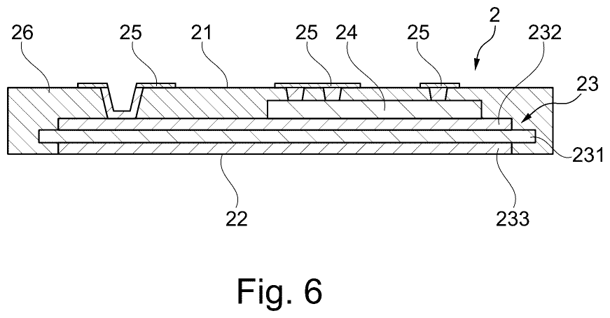

The electrical modules from FIG. 1 may be embodied in embodiments according to FIG. 6. According to this figure, the electrical module 2 includes a ceramic circuit carrier 23, an electrical component 24, and electrical contacts 25. The electrical component 24 is a power semiconductor, for example.

The ceramic circuit carrier 23 includes an insulating ceramic layer 231, a top metallization layer 232 arranged on the top side of the ceramic layer 231, and an optional lower metallization layer 233 arranged on the underside of the ceramic layer 231. The electrical component 24 is arranged on the top metallization layer 232. The ceramic circuit carrier 23 and the electrical component 24 are arranged in a substrate 26 that defines the external dimensions of the electrical module 2. The substrate 26 is, for example, an encapsulating compound, in which the ceramic circuit carrier 23 and the electrical component 24 are embedded, or a printed circuit board, in which the ceramic circuit carrier and the electrical component are embedded.

The substrate 26 includes a top side 21 that also forms the top side of the electrical module 2. An underside of the substrate 26 extends flush with the lower metallization layer 233. The underside of the substrate 26 and the lower metallization layer 233 form the underside 22 of the electrical module 2. According to the embodiment in FIG. 1, the underside 22 is connected to a heat sink 3 via a thermal interface material 91.

The top side 21 of the electrical module 2 has a plurality of electrical contacts 25 that serve to make contact with corresponding contacts of the printed circuit board 1. The electrical contacts 25 include vias to an underside potential and to top side potentials of the electrical component 24. For example, the electrical contacts 25 provide a source terminal, a gate terminal, and a drain terminal of the electrical component 24.

The ceramic circuit carrier 23 having the ceramic layer 231 is used on the one hand to electrically insulate the electrical component 24 arranged on the ceramic circuit carrier 23 from the heat sink and at the same time provides a thermal connection to the heat sink.

The disclosure is not limited to the embodiments described above and different modifications and improvements may be made without deviating from the concepts described here. It is furthermore pointed out that any of the features described may be used separately or in combination with any other features, provided that they are not mutually exclusive. The disclosure extends to and includes all combinations and sub-combinations of one or more features which are described here. If ranges are defined, these ranges therefore include all the values within these ranges as well as all the partial ranges that lie within a range.

1. A printed circuit board assembly comprising:
a printed circuit board having:
a top side;
an underside;
a plurality of metal layers; and
a plurality of electrically insulating layers; and
a metal heat sink on which the underside of the printed circuit board rests at least in certain areas,
wherein the metal heat sink has a heat sink potential, and
wherein a lowest metal layer of the plurality of metal layers of the printed circuit board is put at the heat sink potential, while the other metal layers of the plurality of metal layers of the printed circuit board have a different electrical potential.

2. The printed circuit board assembly of claim 1, wherein the lowest metal layer is a lower outer layer of the printed circuit board.

3. The printed circuit board assembly of claim 1, wherein the lowest metal layer is a lowest inner layer of the metal layers of the printed circuit board.

4. The printed circuit board assembly of claim 1, wherein the lowest metal layer of the printed circuit board and the metal heat sink are connected to each other by a short-circuit path.

5. The printed circuit board assembly of claim 1, further comprising:
at least one screw connection that presses the printed circuit board against the metal heat sink.

6. The printed circuit board assembly of claim 5, wherein the lowest metal layer of the printed circuit board is put at the heat sink potential via the at least one screw connection.

7. The printed circuit board assembly of claim 6, wherein the at least one screw connection comprises a metal screw extending through a mounting hole of the printed circuit board and screwed into the metal heat sink,
wherein the mounting hole has a circumferential metallization in a printed circuit board plane in which the lowest metal layer is formed, and
wherein the circumferential metallization is in electrical contact with or formed by the lowest metal layer.

8. The printed circuit board assembly of claim 1, wherein the heat sink potential of the metal heat sink is equal to a ground potential.

9. The printed circuit board assembly of claim 1, wherein the other metal layers of the printed circuit board, which are not subjected to the heat sink potential, are subjected to a high-voltage potential.

10. The printed circuit board assembly of claim 1, wherein the lowest metal layer covers at least two-thirds of a surface of the printed circuit board.

11. The printed circuit board assembly of claim 1, further comprising:
at least one electrical module arranged on the underside of the printed circuit board,
wherein the metal heat sink has a cavity into which the at least one electrical module protrudes, and
wherein the printed circuit board rests on the metal heat sink adjacent to the cavity.

12. The printed circuit board assembly of claim 11, wherein the at least one electrical module comprises:
a ceramic circuit carrier having an insulating ceramic layer and an upper metallization layer arranged on a top side of the insulating ceramic layer;
an electrical component arranged on a top side of the upper metallization layer and electrically connected thereto;
a top side arranged on the underside of the printed circuit board; and
an underside.

13. The printed circuit board assembly of claim 12, wherein the underside of the at least one electrical module is thermally connected to the metal heat sink via a thermal interface material.

14. The printed circuit board assembly of claim 11, wherein the at least one electrical module comprises semiconductor components.

15. The printed circuit board assembly of claim 1, wherein the underside of the printed circuit board rests on the metal heat sink via a thermal interface material.

16. The printed circuit board assembly of claim 14, wherein the semiconductor components are power semiconductors.
